(19) United States
(12) Patent Application Publication
(10) Pub. No.: US 2025/0338547 A1
(43) Pub. Date: Oct. 30, 2025

(54) GATE TRENCH POWER SEMICONDUCTOR DEVICES HAVING SPLIT GATE ELECTRODES

(71) Applicant: Wolfspeed, Inc., Durham, NC (US)

(72) Inventors: Daniel J. Lichtenwalner, Raleigh, NC (US); Shane Stein, Morrisville, NC (US); Woongsun Kim, Cary, NC (US); Naeem Islam, Morrisville, NC (US)

(21) Appl. No.: 18/646,883

(22) Filed: Apr. 26, 2024

(51) Int. Cl. H01L 29/78; H01L 29/06; H01L 29/16; H01L 29/423

(52) U.S. Cl. CPC H10D 30/668; H10D 62/10; H10D 62/8325; H10D 64/513

(57) ABSTRACT

Gate trench semiconductor devices having reduced capacitance between a semiconductor layer structure and a gate electrode thereof. For example, a semiconductor device may include a semiconductor layer structure that comprises a drift region having a first conductivity type, a well layer having a second conductivity type, and a source region having the first conductivity type; a first gate trench extending into an upper portion of the semiconductor layer structure; a first dielectric layer within the first gate trench and conforming to an interior perimeter of the first gate trench; and a first gate electrode within the first gate trench and on the first dielectric layer. The gate electrode may have first and second portions that are spaced apart from each other by a second dielectric layer.

### TECHNICAL FIELD

The present inventive concepts relate to power semiconductor devices and, more particularly, to power semiconductor devices having gate trenches and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode (which may act as the gate terminal or may be electrically connected to the gate terminal) may be provided adjacent to the channel region and separated from the channel region by a thin oxide layer.

A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present inventive concepts that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have the gate electrode in a gate trench within the semiconductor layer structure, which are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench and conforming to an interior perimeter of the first gate trench. The semiconductor device may include a first gate electrode within the first gate trench and on the first dielectric layer, the first gate electrode having first and second portions that are spaced apart from each other by a second dielectric layer.

In some embodiments, at least a portion of the first dielectric layer on a bottom surface of the first gate trench may be free from vertical overlap with the first gate electrode.

In some embodiments, the first and second portions may be free from contact with each other along an entirety of the first gate trench.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer.

In some embodiments, the first dielectric layer may include an oxide.

In some embodiments, the first dielectric layer may have a substantially uniform thickness along the interior perimeter of the first gate trench.

In some embodiments, the first dielectric layer may have a first thickness along a first sidewall of the first gate trench and may have a second thickness along a bottom surface of the first gate trench that is greater than the first thickness.

In some embodiments, the semiconductor layer structure may further include a trench shielding region having the second conductivity type below the first gate trench.

In some embodiments, the semiconductor layer structure may further include a shielding region that extends into the drift region. In some embodiments, the semiconductor device may include a second gate trench extending into the upper portion of the semiconductor layer structure, and the shielding region may be in between the first gate trench and the second gate trench.

In some embodiments, the second dielectric layer may include an oxide.

In some embodiments, the second dielectric layer may be an intermetal dielectric layer.

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending in the semiconductor layer structure. The semiconductor device may furthermore include a first dielectric layer within the first gate trench and conforming to an interior perimeter of the first gate trench. The semiconductor device may in addition include a first gate electrode within the first gate trench and on the first dielectric layer, the first gate electrode having first and second portions that are spaced apart from each other by a second dielectric layer. A maximum width of the second dielectric layer between the first portion and the second portion of the first gate electrode in a transverse direction perpendicular to an extension direction of the first gate trench may be equal to a maximum distance between the first portion and the second portion of the first gate electrode in the transverse direction.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer. In some embodiments, the first dielectric layer may include an oxide.

In some embodiments, at least a portion of the first dielectric layer on a bottom surface of the first gate trench may be free from overlap with the first gate electrode in a vertical direction perpendicular to the transverse direction.

In some embodiments, the first dielectric layer may have a substantially uniform thickness along the interior perimeter of the first gate trench.

In some embodiments, the first dielectric layer may have a first thickness along a first sidewall of the first gate trench and may have a second thickness along a bottom surface of the first gate trench that is greater than the first thickness.

In some embodiments, the semiconductor layer structure may further include a trench shielding region having the second conductivity type below the first gate trench. According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench and conforming to surfaces of the drift region, well layer, and source region that are exposed by the first gate trench. The semiconductor device may include a first gate electrode within the first gate trench and on the first dielectric layer, the first gate electrode having first and second portions that are spaced apart from each other by a second dielectric layer. The first portion and the second portion of the gate electrode may directly contact the second dielectric layer.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer.

In some embodiments, the first dielectric layer may include an oxide.

In some embodiments, at least a portion of the first dielectric layer on a bottom surface of the first gate trench may be free from overlap with the first gate electrode in a vertical direction perpendicular to an extension direction of the first gate trench.

According to some embodiments of the inventive concepts of the present disclosure, a method may include providing a semiconductor layer structure that may include a drift region having a first conductivity type. The method may also include forming a gate trench that extends in a longitudinal direction in the semiconductor layer structure. The method may also include forming a first dielectric layer along an interior perimeter of the gate trench. The method may also include forming a gate electrode layer on the first dielectric layer in the gate trench. The method may include etching the gate electrode layer in the gate trench, resulting in a gate electrode having a first portion and a second portion that are spaced apart from each other in a direction perpendicular to the longitudinal direction. The method may also include forming a second dielectric layer between the first portion of the gate electrode and the second portion of the gate electrode.

In some embodiments, the method may include forming an additional gate electrode layer on the second dielectric layer between the first and second portions of the gate electrode.

In some embodiments, the method may include forming a trench shielding region underneath the gate trench into the drift region.

In some embodiments, the first dielectric layer has a first thickness along a first sidewall of the gate trench and has a second thickness along a bottom surface of the gate trench that is greater than the first thickness.

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench, the first dielectric layer on a bottom surface of the first gate trench. The semiconductor device may include a first gate electrode within the first gate trench and on the first dielectric layer, the first gate electrode having first and second portions that are spaced apart from each other by a second dielectric layer.

In some embodiments, at least a portion of the first dielectric layer on a bottom surface of the first gate trench may be free from vertical overlap with the first gate electrode.

In some embodiments, the first gate electrode further may include a connecting portion between and directly connected to the first and second portions of the first gate electrode, and the connecting portion may be at least partially within the first gate trench.

In some embodiments, the connecting portion may overlap vertically with the second dielectric layer, and a bottom surface of the connecting portion may directly contact the second dielectric layer.

The present disclosure is not limited to the examples of embodiments provided in this summary section, and other examples and embodiments will be apparent to those of ordinary skill in the art upon review of the detailed description and accompanying figures.

### BRIEF DESCRIPTION OF THE DRAWINGS

FIG. 1 is a semi-log graph illustrating the relationship between the lifetime of the gate oxide layer as a function of applied electric field strength.

FIG. 2A is a schematic cross-sectional view of a unit cell of a gate trench power MOSFET.

FIG. 2B is a schematic cross-sectional view of a unit cell of a gate trench power MOSFET.

FIG. 2C is a schematic cross-sectional view of a unit cell of a gate trench power MOSFET.

FIG. 3A is a schematic top view of a gate trench silicon carbide power MOSFET according to certain embodiments of the present inventive concepts.

FIG. 3B is a schematic top view of the gate trench silicon carbide power MOSFET of FIG. 3A with various of the upper metal and dielectric layers removed.

FIG. 3C is a schematic top view of a portion A of the gate trench silicon carbide power MOSFET of FIGS. 3A and 3B with various of the upper metal and dielectric layers removed.

FIG. 3D is a schematic cross-sectional view of the gate trench silicon carbide power MOSFET of FIGS. 3A-3C that is taken along line 3D-3D of FIG. 3C. FIG. 3E is a schematic cross-sectional view of the gate electrode and surrounding structures of the gate trench silicon carbide power MOSFET of FIG. 3D.

FIG. 4 is a schematic cross-sectional view of a gate trench silicon carbide power MOSFET according to certain embodiments of the present inventive concepts taken along 3D-3D of FIG. 3C.

FIG. 5A is a schematic top view of a portion A of a gate trench silicon carbide power MOSFET according to certain embodiments of the present inventive concepts with various of the upper metal and dielectric layers removed. FIG. 5B is a schematic cross-sectional view of the gate trench silicon carbide power MOSFET of FIG. 5A that is taken along line 5B-5B of FIG. 5A. FIG. 5C is a schematic cross-sectional view of the gate electrode and surrounding structures of the gate trench silicon carbide power MOSFET of FIGS. 5A and 5B.

FIG. 6 is a schematic cross-sectional view of a gate trench silicon carbide power MOSFET according to certain embodiments of the present inventive concepts taken along 5B-5B of FIG. 5A.

FIGS. 7A-7D are schematic cross-sectional view of a gate trench silicon carbide power MOSFETs according to further embodiments of the present inventive concepts.

FIG. 8 is a schematic cross-sectional view of a modified version of the gate trench silicon carbide power MOSFET of FIG. 3A-3E, according to some embodiments.

FIG. 9 is a flow chart illustrating a method of fabricating the gate trench silicon carbide power MOSFET of FIGS. 3A-3E.

FIGS. 10A-10D are schematic cross-sectional views illustrating operations of a method of fabricating the gate trench silicon carbide power MOSFET of FIGS. 3A-3E.

FIGS. 11A-11B are schematic cross-sectional views illustrating operations of a method of fabricating the gate trench silicon carbide power MOSFET of FIGS. 5A-5C.

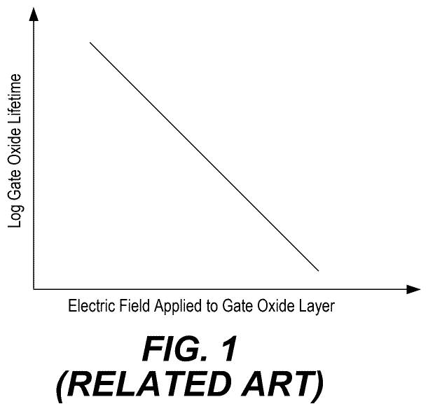

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches during reverse blocking operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the bottom surface of the semiconductor layer structure) toward the top surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottom of the gate trenches). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shielding regions” (also called “trench shields” or “bottom shields”) are often provided underneath the gate trenches of gate trench power MOSFETs in order to reduce the electric field levels in the gate oxide layer during reverse blocking operation. These trench shielding regions are formed by doping the portions of the semiconductor layer structure underneath the gate trenches with dopants having the same conductivity type as the dopants included in the channel regions of the device. The trench shielding regions are typically formed via one or more ion implantation processes in which p-type dopant ions (for an n-type MOSFET) are implanted through the bottom surfaces of the gate trenches. The trench shielding regions may, for example, extend downwardly 0.5 to 1.0 microns or more from the bottoms of the gate trenches into the semiconductor layer structure of the device, and are moderately to highly doped regions. The trench shielding regions are electrically connected to the source terminal of the MOSFET by p-type trench shielding region connection patterns. These trench shielding connection patterns may be in and/or outside the active region of the device.

More recently, gate trench power MOSFETs have been suggested that include additional shielding regions that are referred to as “support shields.” The support shields are formed in the semiconductor layer structure between adjacent gate trenches and, like the trench shielding regions, may comprise highly doped semiconductor regions having the same conductivity type as the channel regions of the MOSFET. The support shields may, for example, extend to the same depth, or a deeper depth in the semiconductor layer structure as the trench shielding regions and may be formed by a high-energy ion implantation process. The support shields may directly connect to the source metallization in the active region of the device.

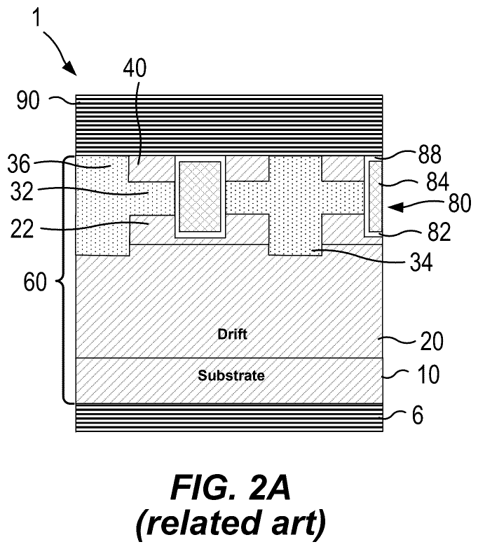

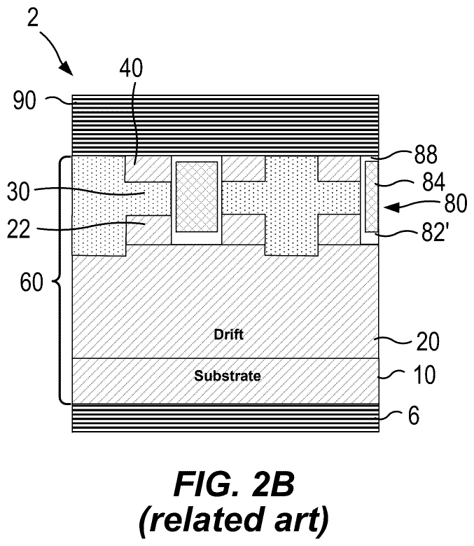

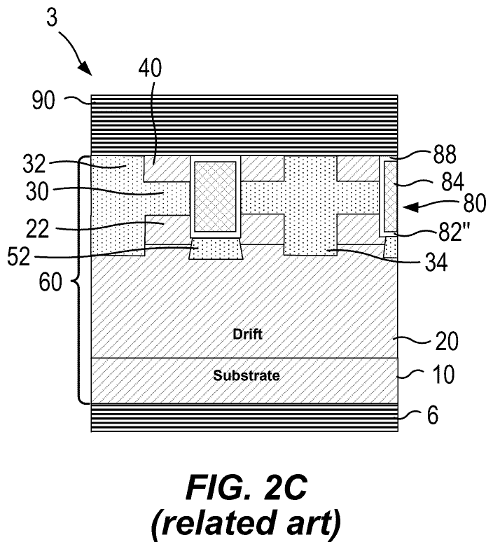

FIG. 2A is a schematic cross-sectional view of a small portion of a silicon carbide power MOSFET 1. The cross-section of FIG. 2A shows one full unit cell of the MOSFET 1 and portions of an adjacent unit cell. As shown in FIG. 2, the MOSFET 1 includes a heavily-doped n-type (n+) silicon carbide semiconductor substrate 10. A lightly-doped n-type (n⁻) silicon carbide drift region 20 is provided on the upper surface of the substrate 10. An n-type silicon carbide JFET region 22 is formed in the upper portion of the drift region 20. The JFET region 22 may be more heavily doped than the remainder of the drift region 20. Moderately-doped (p) silicon carbide p-type wells 32 (also referred to as “p-wells”) are provided on the upper surface of the n-type JFET region 22. Heavily-doped (n+) n-type silicon carbide source regions 40 are formed in upper portions of the p-wells 32. The substrate 10, drift region 20, p-wells 32, and source regions 40 are part of a semiconductor layer structure 60 of the MOSFET 1.

The semiconductor layer structure 60 further includes p-type support regions 34 (that may be deep well regions or support regions) that extend downwardly from the p-wells 32. The p-type support region 34 may be moderately (p) or heavily doped (p⁺) silicon carbide regions, and may be or may include support shield regions. The semiconductor layer structure 60 may include well contact regions 36 which may electrically connect the p-type wells 32 with a source metallization layer 90. In some embodiments, the p-wells 32, p-type support regions 34, and p-type well contact regions 36, may be in contact with one another and may be a unitary or integral region.

As is further shown in FIG. 2A, plurality of gate trenches 80 are formed in the upper portion of the semiconductor layer structure 60. A gate oxide layer 82 is formed conformally within each gate trench 80, and gate electrodes 84 are formed in the gate trenches 80 on the gate oxide layers 82. An intermetal dielectric pattern 88 covers the gate electrodes 84. The source metallization layer 90 is formed on the intermetal dielectric pattern 88 and on the heavily-doped n-type source regions 40 and upper portions of the well contact regions 36. A drain contact 6 is formed on the lower surface of the substrate 10

As shown, the p-type support regions 34 may extend downwardly part or all of the way through the JFET region 22. Likewise, the gate trenches 80 may also extend downwardly part or all of the way through the JFET region 22. As a result, the JFET region 22 may horizontally overlap the p-type support regions 34 and one or both of the gate trenches 80. As used herein, two elements of a semiconductor device are considered to “horizontally overlap” if an axis that is parallel to the major surfaces of a semiconductor layer structure intersects both elements. The p-type support regions 34 may act to reduce the electric field levels that form in gate oxide layers 82 during reverse blocking operation.

The gate electrode 84 and the gate oxide layer 82 form a capacitor with the p-wells 32. The capacitance of this capacitor affects the switching speed of the power MOSFET 1, with a higher capacitance leading to a slower switching speed. As the gate electrode 84 follows along the entire trench periphery, the gate capacitance of the power MOSFET 1 may be relatively high.

FIG. 2B is a schematic cross-sectional view of a small portion of a silicon carbide power MOSFET 2, which demonstrates one way to reduce the intensity of the electric field in the gate oxide layer 82′ as compared with the gate oxide layer 82 of FIG. 2A, and also lower the gate capacitance. As seen the power MOSFET 2 of FIG. 2B, the gate oxide layer 82′ may be relatively thicker at a bottom portion of the gate trench 80, and may have a greater vertical thickness on the lower corners and bottom surface of the gate electrode 84. This may reduce the electric field in the gate oxide layer 82′, and may also reduce the gate capacitance of the power MOSFET 2 in the bottom of the gate trench 80. However, the gate oxide layer 82′ may still be prone to breakdown.

FIG. 2C is a schematic cross-sectional view of a small portion of a silicon carbide power MOSFET 3, which demonstrates another way to reduce the intensity of the electric field in the gate oxide layer 82″ as compared with the gate oxide layer 82 of FIG. 2A by providing p-type silicon carbide trench shielding regions 52 that act as a shield that reduces the electric field values directly underneath the gate trenches 80. The electric field, however, will tend to extend upwardly on both sides of each trench shielding region 52. As such, the electric field tends to be highest in the portions of the gate oxide layers 82″ that are not directly protected by the trench shielding regions 52, such as the lower sidewalls and lower corners of each gate oxide layers 82″. As discussed above, electric field crowding effects occur in the lower corners of each gate oxide layer 82″, further increasing the intensity of the electric field in these portions of the gate oxide layers 82″. Thus, while the trench shielding regions 52 help reduce the electric field levels in the gate oxide layers 82″, the lower corners of the gate oxide layers 82″ are typically only partially protected, and these lower corners are the portions of the gate oxide layers 82″ that are most susceptible to breakdown due to the electric field crowding effects.

Accordingly, pursuant to some embodiments of the present disclosure, a total gate area of a trenched MOS switching devices (e.g., trenched MOSFET or IGBT) may be reduced, which may lead to faster switching with lower power loss. Also, the gate electric field can be lowered leading to a more reliable device (longer gate oxide lifetime). This may be of particular importance to wide bandgap material devices (SiC, GaN, Ga₂O₃) as the gate electric fields are necessarily higher in semiconductors which themselves can maintain higher electric fields than typical semiconductors (Ge, Si, GaAs). The present disclosure may provide trenched MOS switching devices in which the gate electrode is divided into first and second regions that are arranged near the p-wells, with at least a portion of the gate electrode removed from a third region that is between the first and second regions. Stated differently, a gate electrode may be absent within at least a portion of the gate trench between the first and second regions.

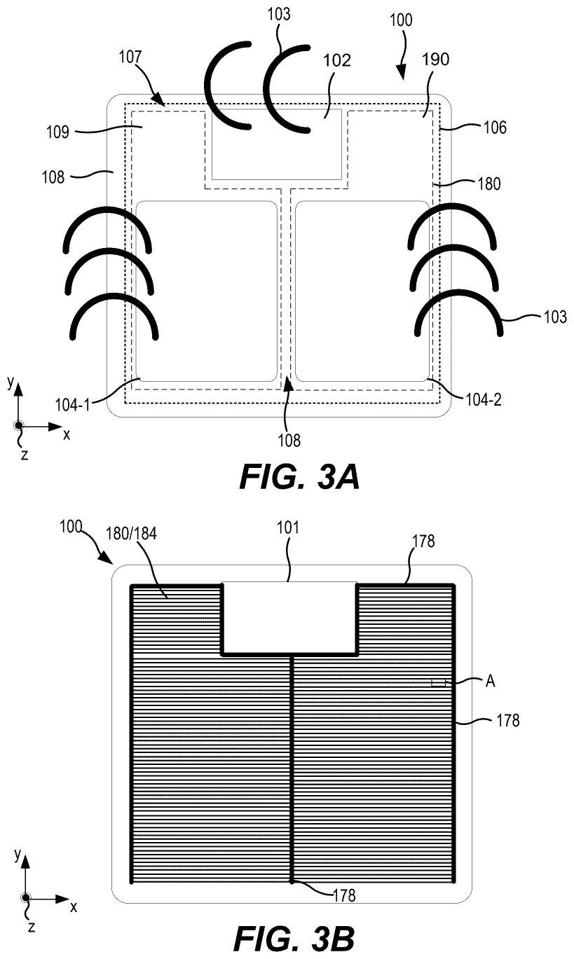

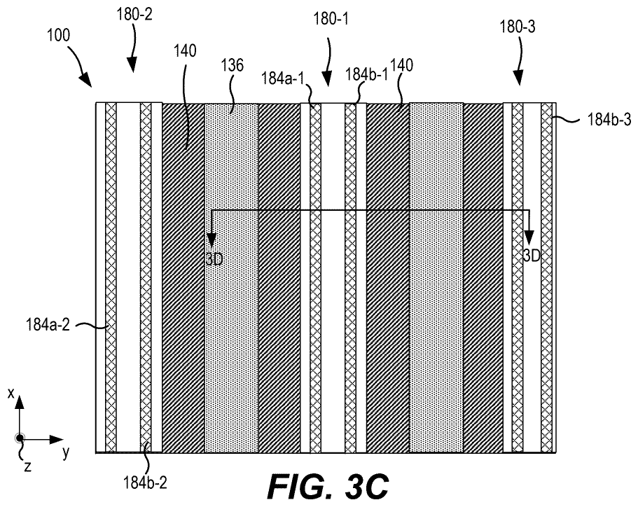

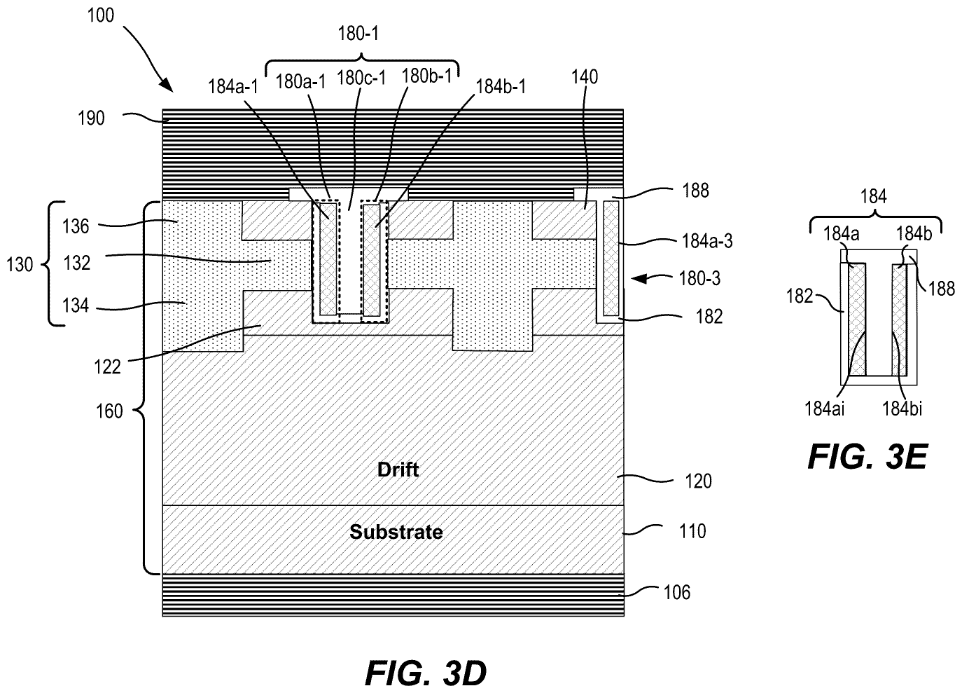

Embodiments of the present inventive concepts will now be described in more detail with reference to FIGS. 3A-11B. It will be appreciated that features of the different embodiments disclosed herein may be combined in any way to provide many additional embodiments. Thus, it will be appreciated that various features of the present inventive concepts are described below with respect to specific examples, but that these features may be added to other embodiments and/or used in place of example features of other embodiments to provide many additional embodiments. Thus, the present inventive concepts should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to certain embodiments of the present inventive concepts. FIG. 3B is a schematic plan view of the power MOSFET 100 with various top-side metal and dielectric layers thereof omitted to show the gate electrodes and gate buses. It will be appreciated that the thicknesses of various of the layers and regions in FIGS. 3A-3B are not necessarily drawn to scale. The same is true with respect to the other figures included in this application.

The power MOSFET 100 includes a semiconductor layer structure 160 (see FIG. 3D) that comprises one or more semiconductor substrates and/or layers. At least one of the semiconductor layers in the semiconductor layer structure 160 may be a silicon carbide layer. Various metal and/or dielectric layers are formed on either side of the semiconductor layer structure 160 and embedded in the semiconductor layer structure 160.

As shown in FIG. 3A, the top-side metal layers include a gate bond pad 102 and one or more source bond pads 104-1, 104-2 that are formed on the upper side of the semiconductor layer structure 160. A metal drain pad 106 (shown as a dotted box in FIG. 3A) is provided on the bottom side of the semiconductor layer structure 160. The gate bond pad 102, the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization layer 190 (indicated by the dashed boxes in FIG. 3A) that electrically connects certain regions of the semiconductor layer structure 160 to the source bond pads 104-1, 104-2. The source bond pads 104-1, 104-2 may be portions of the source metallization layer 190 that are exposed through openings in the protective layer 109 or may be separate metal layers. The source metallization layer 190 may generally overlie or correspond to an “active region” 107 of the power MOSFET 100 where the unit cell transistors are located. An inactive region 108 of power MOSFET 100 surrounds the active region 107 and may also extend through portions of the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 103 are shown in FIG. 3A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 3B is another plan view of power MOSFET 100 with the gate and source bond pads 102, 104, the protective layer 109, the source metallization layer 190, the intermetal dielectric layers 188 and various other metal and dielectric layers removed to show the gate electrodes 184 that are formed in the gate trenches 180 in the semiconductor layer structure 160. A patterned field oxide layer (not shown) is formed on the semiconductor layer structure 160 in the inactive region 108 of the MOSFET 100. The field oxide layer may be a relatively thick oxide layer (e.g., ten to twenty times thicker than the gate oxide layers that are discussed below). A polysilicon layer 101 may be formed on the field oxide layer and may be formed in the region where the gate bond pad 102 is formed so that the gate bond pad 102 vertically overlaps the field oxide layer and the polysilicon layer 101. As used herein, two elements of a semiconductor device are considered to “vertically overlap” if an axis that is perpendicular to the major surfaces of a semiconductor layer structure intersects both elements.

One or more gate buses 178 are provided that extend around the periphery of the active region 107 and/or through the active region 107. The field oxide layer typically runs underneath each gate bus 178 as well as underlying the gate bond pad 102. The gate buses 178 are electrically connected to the gate bond pad 102, often through gate resistors (not shown). A plurality of gate trenches 180 (see FIG. 3C) are formed throughout the active region 107. A gate electrode 184 is formed in each gate trench 180. In the depicted MOSFET 100, the gate electrodes 184 extend horizontally across the semiconductor layer structure 160. In other cases, the gate electrodes 184 may extend vertically across the semiconductor layer structure 160, or both horizontally-extending and vertically-extending gate electrodes 184 can be provided to form a grid-like gate electrode structure. The gate electrodes 184 may be connected to the gate pad 102 through the gate buses 178. The gate electrodes 184 may comprise, for example, a doped polysilicon pattern. The gate buses 178 may comprise polysilicon and/or metal structures in example embodiments and typically are in the inactive region 108 of power MOSFET 100.

FIG. 3C is a schematic top view of a portion A of the gate trench silicon carbide power MOSFET of FIGS. 3A and 3B with various of the upper metal and dielectric layers removed. FIG. 3D is a schematic cross-sectional view of the gate trench silicon carbide power MOSFET of FIGS. 3A-3C that is taken along line 3D-3D of FIG. 3C. FIG. 3E is a schematic cross-sectional view of the gate electrode and surrounding structures of the gate trench silicon carbide power MOSFET of FIG. 3D. FIG. 3D illustrates about one and a half unit cells of the power MOSFET 100.

As shown in FIG. 3D, the power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). It should be noted that while the substrate 110 is depicted as a relatively thin layer, this is done to allow enlarging the thickness of other layers and regions in FIG. 3D, and it will be appreciated that the substrate 110 will typically be much thicker than shown. The thickness of various other layers of power MOSFET 100 likewise may not be shown to scale in order to allow other portions of the devices to be enlarged in the figures.

A lightly-doped n-type (n−) silicon carbide drift layer 120 (which also may be referred to herein as a drift region 120) is provided on an upper surface of the substrate 110. Typically, the drift layer 120 is formed via an epitaxial growth process and is doped during growth. The n-type drift region 120 may have, for example, a doping concentration of 5×10¹⁵ to 5×10¹⁷ dopants/cm³. The n-type drift region 120 may be a thick region, having a vertical height above the substrate 110 of, for example, 3-50 microns, and can be doped during growth. An upper portion of the n-type drift region 120 may comprise an n-type JFET region 122 that is more heavily doped than the lower portion of the n-type drift region 120. The n-type JFET region 122 may have an n-type dopant concentration of, for example, 5×10¹⁶ to 1×10¹⁸. The n-type JFET region 122 is considered to be part of the drift region 120.

The drift layer 120 and the substrate 110 together act as a common drain region for the power MOSFET 100. The drain pad 106 is formed on the substrate 110 opposite the drift region 120.

Still referring to FIG. 3D, a moderately-doped (p) p-type silicon carbide well layer 132 is formed on the upper surface of the n-type JFET region 122 or in an upper portion of the n-type drift region 120 (i.e., the upper portion of the n-type drift region 120 is converted into the well layer 132). The moderately-doped (p) p-type silicon carbide well layer 132 may be formed either by epitaxial growth or by implanting p-type dopant ions into the upper portion of the n-type drift region 120 to convert the upper portion of the n-type drift layer 120 into the p-type silicon carbide well layer 132. In example embodiments, the moderately-doped p-type well layer 132 may have a p-type dopant concentration of, for example, between 5×10¹⁶ to 1×10¹⁸.

A heavily-doped (n+) n-type silicon carbide source layer 140 is formed on the p-type silicon carbide well layer 132. The heavily-doped n-type silicon carbide source layer 140 may be formed by ion implantation. The heavily-doped n-type silicon carbide source layer 140 may have a doping concentration of, for example, between 1×10¹⁹ atoms/cm³ and 5×10²¹ atoms/cm³.

A p-type well contact region 136 may be provided in the semiconductor layer structure 160, and may have an upper surface that is coplanar with an upper surface of the heavily-doped n-type silicon carbide source layer 140. The well contact region 136 may extend as a stripe between adjacent source regions 140 (as shown), or may appear as islands in a single continuous source region 140, as known in the art.

As is further shown in FIG. 3D, p-type support regions 134 are provided that extend downwardly from the p-wells 132. The p-type support regions 134 may be moderately or heavily doped (p⁺) silicon carbide regions. For example, each p-type support region 134 may have a doping concentration between about 5×10¹⁶ and 1×10²². In other embodiments, each p-type support region 134 may have a doping concentration between about 1×10¹⁸ and 1×10²⁰, between about 1×10¹⁹ and 1×10²¹, between about 1×10¹⁷ and 1×10¹⁹, between about 1×10¹⁷ and 1×10²⁰, or between about 1×10¹⁸ and 1×10²¹. The p-type support region 134 may have a doping concentration that is graded with depth. In example embodiments, each p-type support region 134 may extend to a depth of between 0.1 microns and 4.0 microns from the upper surface of the semiconductor layer structure 160. In other embodiments, the depth of each p-type support region 134 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the p-type support regions 134 may be matched with any of the above-listed depths for the p-type support regions 134. The p-type support region 134 may act to reduce the electric field levels that form in gate oxide layers 182. The p-type silicon carbide well layer 132, p-type well contact regions 136, and the p-type silicon carbide support region 134 may together constitute a p-type region 130.

The n-type silicon carbide substrate 110, the n-type silicon carbide drift layer 120 (including the JFET region 122), the p-type silicon carbide well layer 132, the n-type silicon carbide source regions 140, the p-type well contact regions 136, and the p-type silicon carbide support region 134 may together comprise the semiconductor layer structure 160 of the power MOSFET 100.

As noted above, a plurality of gate trenches 180 are formed in the upper portion of the semiconductor layer structure 160. While only one full gate trench 180-1 and a portion of a third gate trench 180-3 are shown in the cross-section of FIG. 3D, it will be appreciated from FIGS. 3A-3C that the MOSFET 100 may include a large number of gate trenches 180. Each gate trench 180 may extend along a longitudinal axis through the semiconductor layer structure 160, and the gate trenches 180 may extend in parallel to each other as shown best in FIG. 3C. It will be appreciated that the longitudinal axes of the gate trenches 180 extend into the page in the view of FIG. 3D. The gate trenches 180 may be formed via an etching process.

A gate oxide layer 182 (which may be a first dielectric layer 182) may be provided in each gate trench 180 to cover the sidewalls and bottom surface of the gate trench 180. In some embodiments, each gate oxide layer 182 may extend onto the upper surface of the semiconductor layer structure 160, as shown in FIG. 3D. In other embodiments, upper surfaces of the gate electrodes 184 may be recessed to be below the upper surface of the semiconductor layer structure 160 and the gate oxide layer 182 may not vertically overlap the semiconductor layer structure 160. Each gate oxide layer 182 may comprise, for example, a silicon oxide (SiO₂) pattern, or may include a high-k dielectric material having suitable properties, such as Al₂O₃, MgO, Si₃N₄, AlN, HfO₂, ZrO₂, LaSiOₓ, BaSiOₓ, and alloys or multilayers formed by these materials. The gate oxide layers 182 may or may not be connected to each other outside the view of FIG. 3D. The gate oxide layers 182 may be formed generally conformally within the respective gate trenches 180. Stated differently, the gate oxide layer 182 may conform to an interior perimeter of the gate trench 180. The interior perimeter of the gate trench 180 may include sidewalls of the gate trench 180 (e.g., first and second sidewalls of the gate trench 180 that are transverse to a longitudinal extension or length of the gate trench 180), and the interior perimeter of the gate trench 180 may include a bottom surface of the gate trench 180 and transition portions between and connecting the sidewalls of the gate trench 180 and the bottom surface of the gate trench 180. In some embodiments, the gate oxide layer 182 may have a relatively uniform thickness along the interior perimeter of the gate trench 180.

A gate electrode 184 may formed in each gate trench 180 on the gate oxide layer 182. The gate electrode 184 may include a first portion 184a and a second portion 184b, which may be on opposite sidewalls of the gate trench 180. A portion of the gate trench 180 between the first portion 184a and the second portion 184b may be free from the gate electrode 184, and may have therein (e.g., may have only therein) the gate oxide layer 182 and/or an intermetal dielectric layer 188 (discussed in greater detail below). With reference to FIG. 3E, gate oxide layer 182 and/or the intermetal dielectric layer 188 (or more broadly, an insulating material) may be on (e.g., directly on or directly contacting) inner sidewalls 184ai and 184bi of the first portion 184a and the second portion 184b of the gate electrode 184.

Stating the above differently, the first gate trench 180-1 may have a first portion 180a-1, a second portion 180b-1, and a third portion 180c-1 between the first portion 180a-1 and the second portion 180b-1. The third portion 180c-1 may be a central portion or middle portion of the first gate trench 180-1 in a horizontal direction (e.g., in a transverse or crosswise direction of the first gate trench 180-1). The first gate electrode 184 may have a first portion 184a-1 thereof that is arranged in the first portion 180a-1 of the first gate trench 180, and the first gate electrode 184 may have a second portion 184b-1 that is arranged in the second portion 180b-1 of the first gate trench 180. The first gate electrode 184 may be absent from the third portion 180c-1 of the first gate trench 180. The first portion 184a-1 of the first gate electrode 184 and the second portion 184b-1 of the first gate electrode 184 may be free from contact with each other along an entirety of the first gate trench 180 (e.g., in a longitudinal or extension direction of the first gate trench 180).

The gate electrodes 184 may comprise conductive material such as a silicide (e.g., NiSi, TiSi, WSi, CoSi), doped polycrystalline silicon (poly-Si), and/or a stable conductor. Other suitable materials for the gate electrode include various metals such as Ti, Ta or W or metal nitrides such as TiN, TaN or WN. The gate oxide layers 182 may insulate the gate electrodes 184 from the semiconductor layer structure 160, thereby preventing the gate electrodes 184 from short circuiting to the semiconductor layer structure 160. Each gate electrode 184 may connect to one of the gate buses 178 (see FIG. 3B). It will be appreciated that in other embodiments the gate electrodes 184 may extend above and onto the upper surface of the semiconductor layer structure 160, with the gate oxide layer 182 insulating the gate electrodes 184 from the upper surface of the semiconductor layer structure 160.

Intermetal dielectric layers 188 (which may be a second dielectric layer 188) may be formed that cover each gate electrode 184. The intermetal dielectric layers 188 may be between and may be on (e.g., directly on or directly contacting) inner sidewalls 184ai and 184bi of the first portion 184a and the second portion 184b of the gate electrode 184. In some embodiments, a width (e.g., a maximum width) of the intermetal dielectric layer 188 between the first portion 184a and the second portion 184b of the gate electrode 184 in a transverse or horizontal direction perpendicular to an extension direction of the gate trench 180 may be equal to a distance (e.g., a maximum distance) between the first portion 184a and the second portion 184b of the gate electrode 184 in the transverse or horizontal direction.

The intermetal dielectric layers 188 may insulate the source metallization layer 190 from the gate electrodes 184, and may insulate the first and second portions 184a, 184b of the gate electrode 184 from each other.

A source metallization layer 190 may be formed on the upper surface of the semiconductor layer structure 160 and on the intermetal dielectric layers 188. Herein, the source metallization layer 190 may also be referred to as the “source contact.” The source metallization layer 190 may comprise a single metal layer or multiple metal layers. Typically multiple metal layers are provided, as the source metallization layer 190 may include a single layer or multi-layer adhesion layer that contacts the semiconductor layer structure 160, one or more barrier layers, and a bulk metal layer (e.g., an aluminum layer).

Still referring to FIG. 3D, it can be seen that MOSFET 100 includes a silicon carbide based semiconductor layer structure 160 that comprises, among other things, a drift region 120 having a first (n) conductivity type, a well layer 132 having a second (p) conductivity type on an upper surface of the drift region 120, and a support region 134 having the second (p) conductivity type. A plurality of gate trenches 180 including a first gate trench 180-1 extends into (i.e., is formed in) an upper portion of the semiconductor layer structure 160. A second gate trench 180-2 also extends into the upper portion of the semiconductor layer structure 160. In some embodiments, a support region 134 may be in between the first and second gate trenches 180-1 and 180-2. Respective gate oxide layers 182 may be in and may conform to an interior perimeter of the first and second gate trenches 180-1 and 180-2. Each of the gate trenches 180-1 and 180-2 may have therein a gate electrode 184 therein, with each of the gate electrodes including a first portion 184a and a second portion 184b. The first portion 184a of the gate electrode 184 and the second portion 184b of the gate electrode 184 may be spaced apart or separated from each other within the first gate trench 180 by the gate oxide layer 182 and/or by the intermetal dielectric layer 188 that is in the first gate trench 180.

The spacing or separation of the first and second portions 184a, 184b of the gate electrodes 184 in the power MOSFET 100 removes an overlap between the gate electrodes 184 and the bottom surfaces of the central portions 180c of the gate trenches 180, which acts to reduce the gate capacitance of the power MOSFET 100 in the bottom of the gate trench 180 and decrease the electric field values in these portions of MOSFET 100. Reducing the electric field values in the central portions 180c of the gate trenches 180 also acts to decrease the electric field values in the gate oxide layers 182 that overlap the bottom surfaces of the central portions 180c of the gate trenches 180. Since these are the portions of the gate oxide layers 182 that would otherwise experience the highest electric field values during reverse blocking operation, it can be seen that the spacing or separation between the first and second portions 184a, 184b of the gate electrodes 184 acts to improve the reliability of MOSFET 100 over MOSFETS 1, 2, and 3. While forming the space between the first and second portions 184a, 184b in the gate electrodes 180 may reduce the overall amount of gate electrode material, thereby increasing the resistance of the gate electrodes 180, the increase in resistance is typically small, since the gate electrode 180 still includes relatively wide transverse sections and relatively tall vertical sections that still overlap sidewalls of the p-type silicon carbide well layer 132. Moreover, the size of the spacing between the first and second portions 184a, 184b of the gate electrodes (i.e., a crosswise width of the central portion 180c of the gate trench 180) may be selected to optimize the tradeoff between gate resistance and reliability.

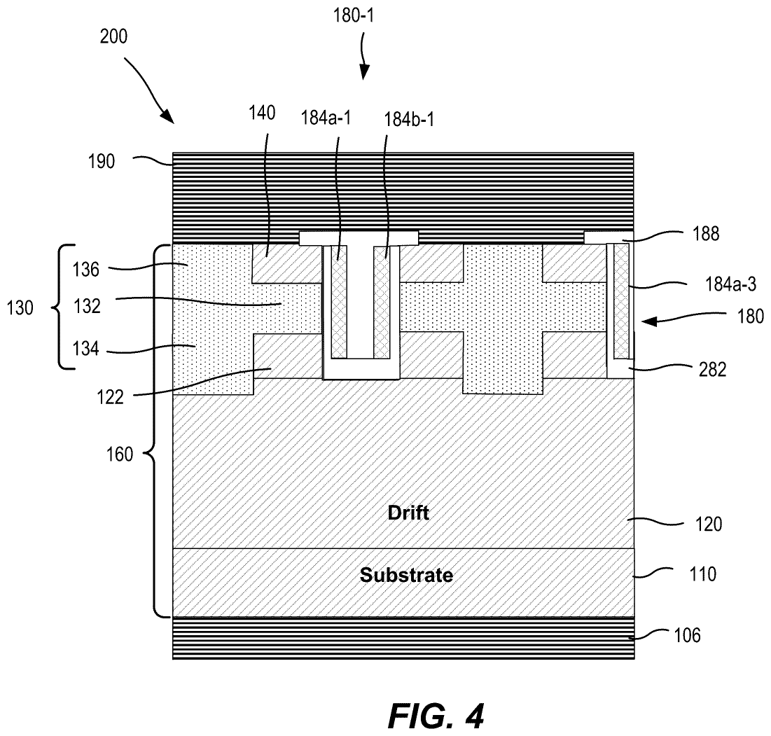

FIG. 4 is a schematic cross-sectional view of a gate trench silicon carbide power MOSFET according to certain embodiments of the present inventive concepts taken along 3D-3D of FIG. 3C. As can be seen by comparing FIG. 3D and FIG. 4, the only difference between MOSFET 100 and MOSFET 200 is that MOSFET 200 may include a gate oxide layer 282 that is thicker along a bottom of the gate trenches 180 than along sidewalls of the gate trenches 180. For example, the gate oxide layer 182 of FIG. 3D may have similar thicknesses on the sidewalls of the gate trenches 180 and on the bottom of the gate trenches 180, with typical values being in a range of 20 nanometers (nm) to 70 nm, inclusive. The gate oxide layer 282 of FIG. 4 may have a thickness along a sidewall of the gate trenches 180 in a range of 20 nm to 70 nm, inclusive, and may have a thickness on the bottom of the gate trenches 180 that is in a range from 40 nm to 100 nm, inclusive. The thickness of the gate oxide layer 282 of FIG. 4 along the bottom of the gate trenches may be 1.2×-3× thicker than the thickness of the gate oxide layer 282 along the sidewalls of the gate trenches 180. Stated differently, the gate oxide layer 282 may conform to the interior perimeter of the gate trench 180, but a thickness of the gate oxide layer 282 may be greater along a bottom surface of the gate trench 180 and on transition portions between and connecting the sidewalls of the gate trench 180 than on the sidewalls of the gate trench 180. The gate oxide layer 282 has a first thickness along a first sidewall of the gate trench 180 and has a second thickness along a bottom surface of the gate trench 180 that is greater than the first thickness.

Providing a gate oxide layer 282 that is thicker along the bottom of the gate trenches may reduce the electric field in the gate oxide layer 282, and may also reduce the gate capacitance of the power MOSFET 200 in the bottom of the gate trench 180. Additionally, the thicker gate oxide layer 282 will exhibit a longer lifetime to breakdown than the thinner gate oxide layer 182 of MOSFET 100. Otherwise, MOSFET 200 may be identical to MOSFET 100, so further description thereof will be omitted.

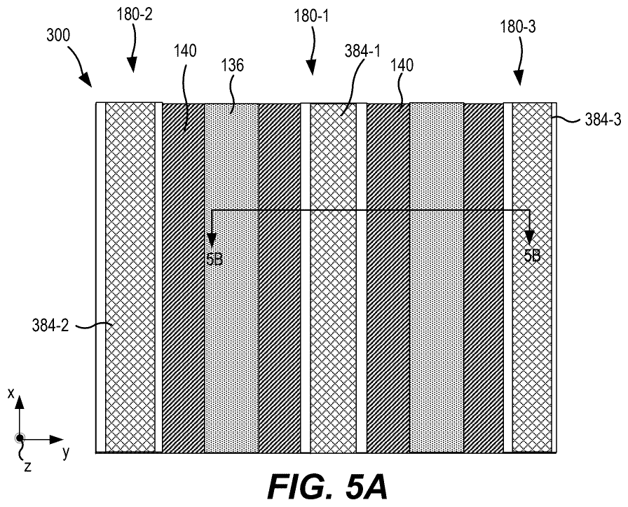

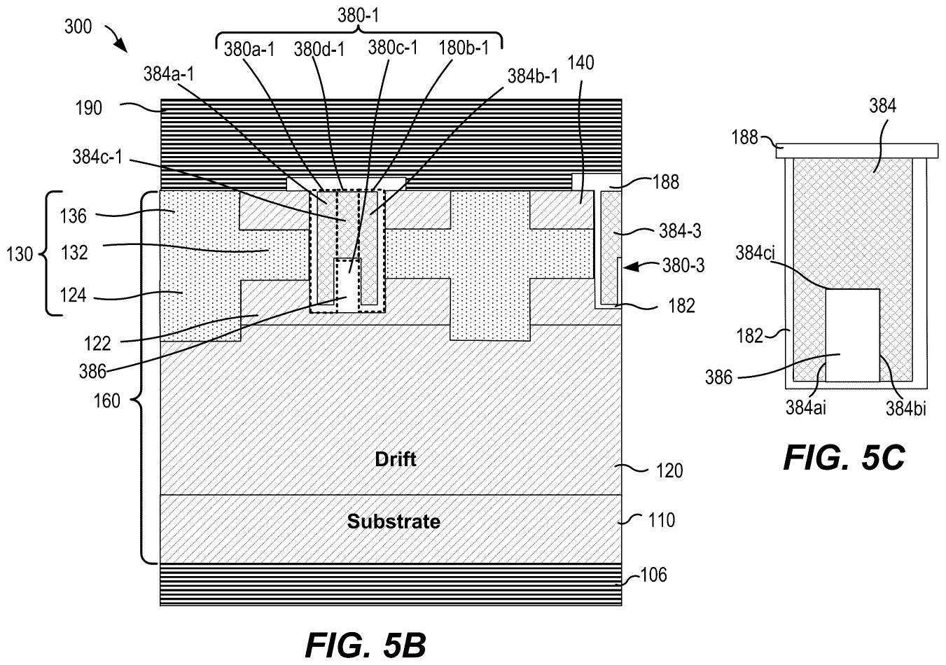

FIG. 5A is a schematic top view of a portion A of a gate trench silicon carbide power MOSFET 300 according to certain embodiments of the present inventive concepts with various of the upper metal and dielectric layers removed. FIG. 5B is a schematic cross-sectional view of the gate trench silicon carbide power MOSFET 300 of FIG. 5A that is taken along line 5B-5B of FIG. 5A. FIG. 5C is a schematic cross-sectional view of the gate electrode and surrounding structures of the gate trench silicon carbide power MOSFET 300 of FIGS. 5A and 5B.

As can be seen by comparing FIGS. 3C, 3D, and 3E with FIGS. 5A, 5B, and 5C the difference between MOSFET 100 and MOSFET 300 is that MOSFET 300 may include a gate electrode 384 that includes a third portion (or middle portion) 384c between a first portion 384a and the second portion 384b. In greater detail, the gate electrode 384 may formed in each gate trench 380 on the gate oxide layer 182. The first portion 384a and the second portion 384b of the gate electrode 384 may be on opposite sidewalls of the gate trench 180. The gate electrode 384 may include a connecting portion 384c that may connect the first portion 184a and the second portion 184b.

Each gate trench 380 may have a first portion 380a, a second portion 380b, a third portion 380c between the first portion 380a and the second portion 380b, and a fourth portion 380d between the first portion 380a and the second portion 380b and vertically overlapping the third portion 380c. The third portion 380c of the gate trench 380 may be closer to the bottom surface of the gate trench 380 than the fourth portion 380d is to the bottom surface of the gate trench 380. The third portion 380c of the gate trench may be closer to a drain contact surface of the substrate 110 than the fourth portion 380d of the gate trench 380 is to the drain contact surface of the substrate 110. The third portion 380c of the gate trench 380 between the first portion 384a and the second portion 384b may be free from the gate electrode 384, and may have therein (e.g., may have only therein) an insulating layer 386, which may be (or may be similar to) the gate oxide layer 182 and/or the intermetal dielectric layer 188. The fourth portion 380d of the gate trench 380 between the first portion 384a and the second portion 384b may have therein the connecting portion 384c of the gate electrode 384. The insulating layer 386 may be on (e.g., directly on or directly contacting) inner sidewalls 384ai and 384bi of the first portion 384a and the second portion 384b of the gate electrode 384 adjacent to the third portion 380c of the gate trench 380. The insulating layer 386 may also be on (e.g., directly on or directly contacting) a lower surface 384ci of the connecting portion 384c of the gate electrode 384 adjacent to the third portion 380c of the gate trench 380.

Stating the above differently, the first gate trench 380-1 may have a first portion 380a-1, a second portion 380b-1, a third portion 380c-1 between the first portion 380a-1 and the second portion 380b-1, and a fourth portion 380d-1 between the first portion 380a-1 and the second portion 380b-1. The third portion 380c-1 may be a lower central portion or lower middle portion of the first gate trench 380-1 in a horizontal direction (e.g., in a transverse or crosswise direction of the first gate trench 380-1). The fourth portion 380d-1 may be an upper central portion or upper middle portion of the first gate trench 380-1 in the horizontal direction (e.g., in the transverse or crosswise direction of the first gate trench 380-1). The first gate electrode 384 may have a first portion 384a-1 thereof that is arranged in the first portion 380a-1 of the first gate trench 380, the first gate electrode 384 may have a second portion 384b-1 that is arranged in the second portion 380b-1 of the first gate trench 380, and the first gate electrode 384 may have a third portion 384c-1 (or connecting portion 384c-1) that is arranged in the fourth portion 380d-1 of the first gate trench 380. The first gate electrode 384 may be absent from the third portion 380c-1 of the first gate trench 380.

The gate electrodes 384 may comprise conductive material such as a silicide (e.g., NiSi, TiSi, WSi, CoSi), doped polycrystalline silicon (poly-Si), and/or a stable conductor. Other suitable materials for the gate electrode include various metals such as Ti, Ta or W or metal nitrides such as TiN, TaN or WN. It will be appreciated that in other embodiments the gate electrodes 384 may extend above and onto the upper surface of the semiconductor layer structure 160, with the gate oxide layer 182 insulating the gate electrodes 384 from the upper surface of the semiconductor layer structure 160. The connecting portion 384c of the gate electrode 384 may be of a similar or different material than the first portion 384a and/or the second portion 384b of the gate electrode 384. In some embodiments, the material selected for the connecting portion 384c may be selected to enhance performance and/or reliability of the power MOSFET 300. For example, the connecting portion 384c may be a material having a lower resistivity than a material constituting the first portion 384a and the second portion 384b. As another example, the first portion 384a and/or second portion 384b may include a material chosen for chemical compatibility with the gate oxide layer 182.

Insulating layer 386 and intermetal dielectric layers 188 may be formed that cover at least some surfaces of each gate electrode 384. The insulating layer 386 and/or intermetal dielectric layers 188 may include SiO₂ or a high-k dielectric material having suitable properties, such as Al₂O₃, MgO, Si₃N₄, AlN, HfO₂, ZrO₂, LaSiOₓ, BaSiOₓ, and alloys or multilayers formed by these materials. In some embodiments, the insulating layer 386 and intermetal dielectric layers 188 may include heavily doped SiO₂, e.g., boron doped and/or phosphorus doped silicates. The insulating layer 386 and intermetal dielectric layers 188 may include materials similar to or different from the gate oxide layers (e.g., gate oxide layer 182). The insulating layer 386 may be between and may be on (e.g., directly on or directly contacting) inner sidewalls 384ai and 384bi of the first portion 384a and the second portion 384b of the gate electrode 384. The insulating layer 386 may be on (e.g., directly on or directly contacting) the lower surface 384ci of the third portion 384c of the gate electrode 384. In some embodiments, a width of the insulating layer 386 between the first portion 384a and the second portion 384b of the gate electrode 384 in a transverse or horizontal direction perpendicular to an extension direction of the gate trench 380 may be equal to a distance between the first portion 384a and the second portion 384b of the gate electrode 384 in the transverse or horizontal direction. In some embodiments, the width of the insulating layer 386 between the first portion 384a and the second portion 384b of the gate electrode 384 in a transverse or horizontal direction perpendicular to an extension direction of the gate trench 380 may be equal to the width of the connecting portion 384c of the gate electrode 384 in the transverse or horizontal direction. In some embodiments, the insulating layer 386 may include a same material as the gate oxide layer 182, and the insulating layer 386 may not be distinguishable from the gate oxide layer 182 that is on and conforms to the interior perimeter of the gate trench 380.

The spacing or separation of the first and second portions 384a, 384b of the gate electrodes 384 in the power MOSFET 300 and the resulting absence from the third portion 380c of the gate trench 380 removes an overlap between the gate electrodes 384 and the bottom surfaces of the lower central portions 380c of the gate trenches 380, which acts to reduce the gate capacitance of the power MOSFET 300 in the bottom of the gate trench 380 and decrease the electric field values in these portions of MOSFET 300. Reducing the electric field values in the central portions 380c of the gate trenches 380 also acts to decrease the electric field values in the gate oxide layers 182 that overlap the bottom surfaces of the central portions 380c of the gate trenches 380. Since these are the portions of the gate oxide layers 182 that would otherwise experience the highest electric field values during reverse blocking operation, it can be seen that the spacing or separation between the first and second portions 384a, 384b of the gate electrodes 384 acts to improve the reliability of MOSFET 100 over MOSFETS 1, 2, and 3. Additionally, providing the connecting portion 384c in the fourth portion 380d of the gate trench 380 may electrically connect the first and second portions 384a, 384b of the gate electrodes, thereby lowering the gate resistance and enabling faster switching relative to the MOSFET 100 of FIGS. 3A-3E. Otherwise, MOSFET 300 may be identical to MOSFET 100, so further description thereof will be omitted.

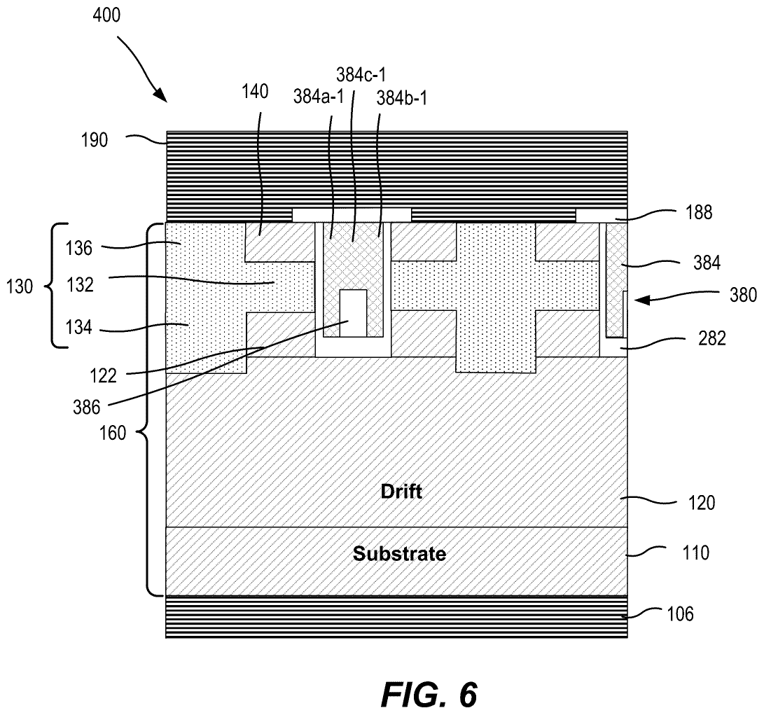

FIG. 6 is a schematic cross-sectional view of a gate trench silicon carbide power MOSFET 400 according to certain embodiments of the present inventive concepts taken along 5B-5B of FIG. 5A. As can be seen by comparing FIGS. 5B and 6, the difference between MOSFET 300 and MOSFET 400 is that MOSFET 400 may include a gate oxide layer 282 that is thicker along a bottom of the gate trenches 380 than along sidewalls of the gate trenches 380. As discussed above, providing a gate oxide layer 282 that is thicker along the bottom of the gate trenches may reduce the electric field in the gate oxide layer 282, and may also reduce the gate capacitance of the power MOSFET 400 in the bottom of the gate trench 180. Otherwise, MOSFET 400 may be identical to MOSFET 300, so further description thereof will be omitted.

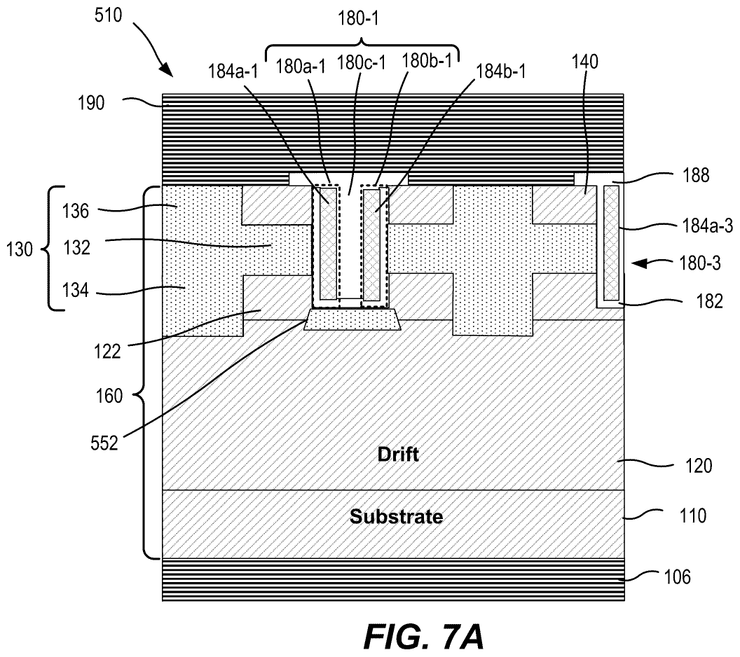

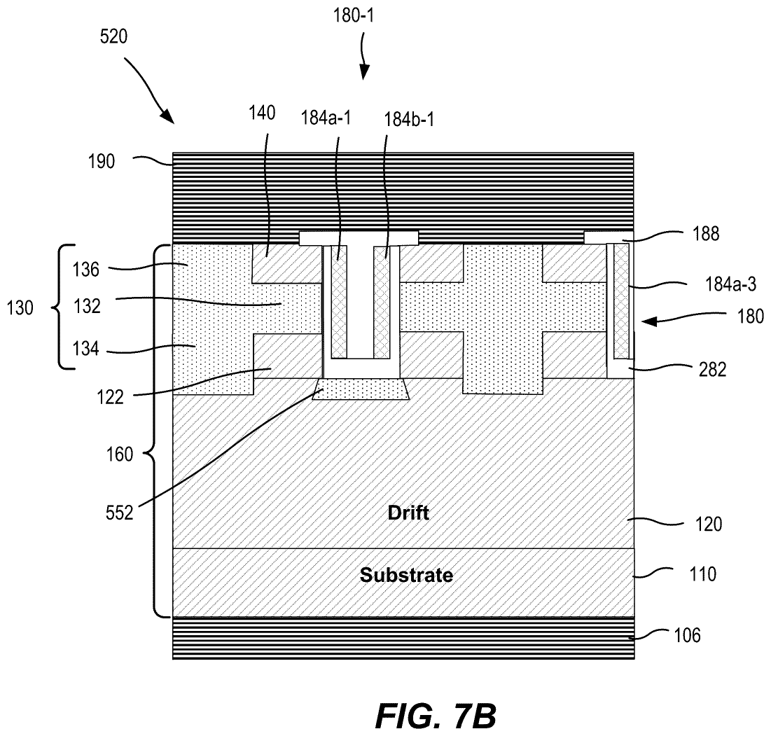

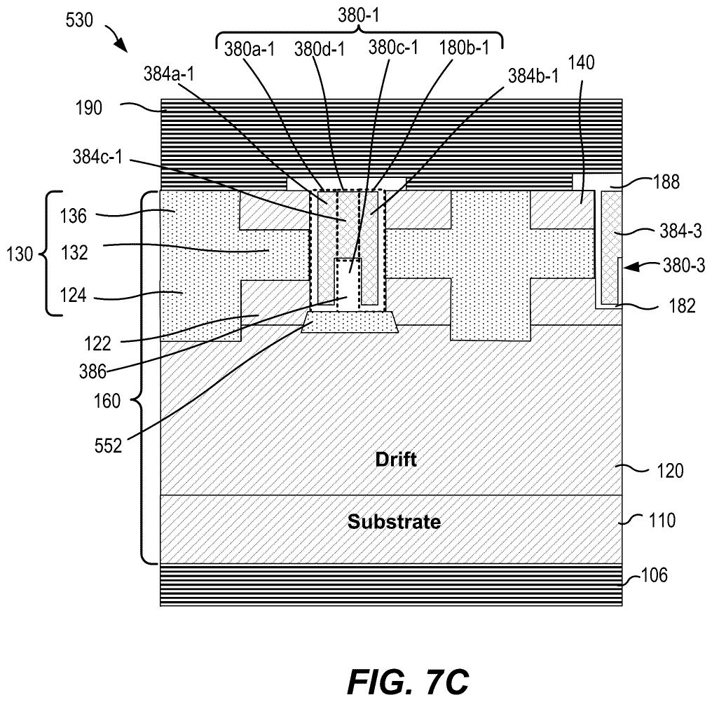

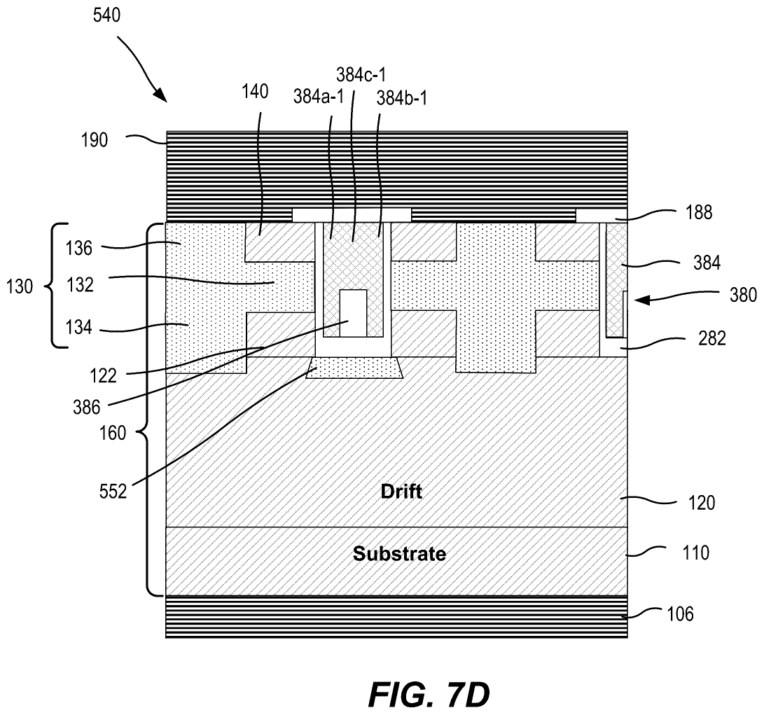

FIGS. 7A-7D are schematic cross-sectional view of gate trench silicon carbide power MOSFETs according to further embodiments of the present inventive concepts. As can be seen by comparing FIGS. 3D, 4, 5B, and 6 respectively with FIGS. 7A-7D, the difference between MOSFET 100 and MOSFET 510, between MOSFET 200 and MOSFET 520, between MOSFET 300 and MOSFET 530, and MOSFET 400 and MOSFET 540 is that MOSFETs 510, 520, 530, and 540 may each include p-type trench shielding regions 552 that are formed underneath the respective gate trenches 180, 380.

Accordingly, in some embodiments, the semiconductor layer structure 160 may also include p-type trench shielding regions 552 that are formed underneath the respective gate trenches 180, 380 typically by implanting p-type dopants through the bottoms of the gate trenches 180, 380. The p-type trench shielding regions 552 may extend underneath the respective gate trenches 180, 380 for all or substantially all of the length of the gate trench 180, 380 and may be moderately (p) or heavily doped (p⁺) silicon carbide regions. For example, each p-type trench shielding region 552 may have a doping concentration between about 1×10¹⁷ and 1×10²¹. In other embodiments, each p-type trench shielding region 552 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In example embodiments, each p-type trench shielding region 552 may extend to a depth of between 0.5 and 3.0 microns from the upper surface of the semiconductor layer structure 160. In other embodiments, the depth of each p-type trench shielding region 552 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the p-type trench shielding regions 552. The p-type trench shielding regions 552 may act to reduce the electric field levels that form in the gate oxide layers 182 or 282 during device operation. The p-type trench shielding regions 552 may be doped to have a higher p-type dopant concentration, a lower p-type dopant concentration, or approximately the same p-type dopant concentration as the p-type support regions 134.

While not shown in FIGS. 7A-7D, electrical connections may be provided that electrically connect the p-type trench shielding regions 552 to the p-type silicon carbide well layer 132. For example, U.S. Pat. Nos. 9,887,287 and 11,610,991 each illustrate designs for metal or p-type silicon carbide trench shield connection patterns that can be used to electrically connect p-type trench shielding regions to a p-type silicon carbide well layer. Any of the p-type silicon carbide trench shield connection patterns disclosed in these patents (each of which is incorporated herein by reference) can be used to electrically connect the p-type trench shielding regions 552 to the p-type silicon carbide well layer 132.

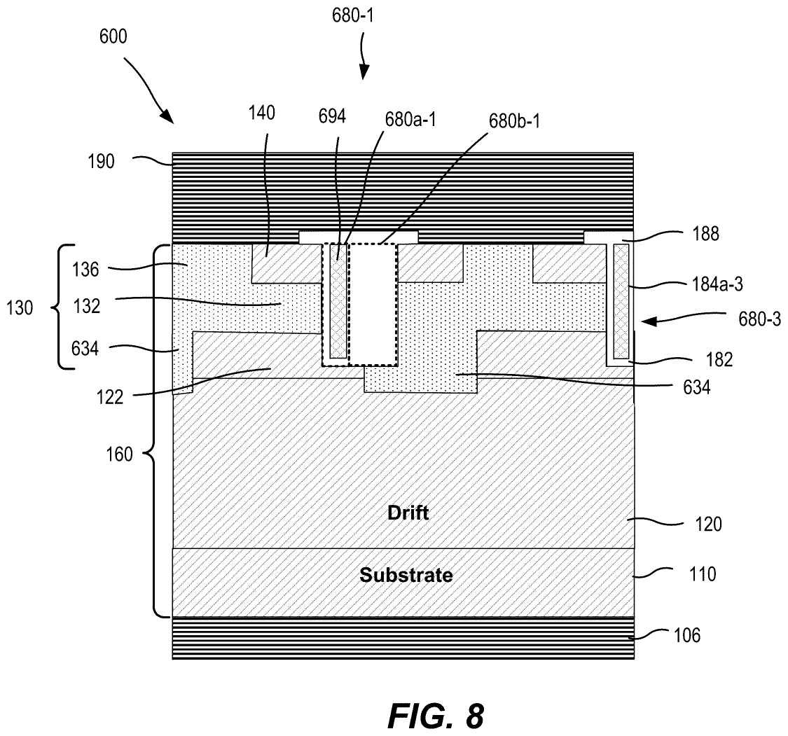

FIG. 8 is a schematic cross-sectional view of a modified version of the gate trench silicon carbide power MOSFET of FIG. 3A-3D, according to some embodiments. Referring to FIG. 8, a structure is shown in which only one side of the gate trench 680 is used as an active channel, and the other side of the gate trench 680 is used for further bottom shielding of the gate trench 680 and the gate oxide layer 182 therein. A moderately-doped (p) p-type silicon carbide well layer 132 is formed on the upper surface of the n-type JFET region 122 or in an upper portion of the n-type drift region 120 (i.e., the upper portion of the n-type drift region 120 is converted into the well layer 132). The moderately-doped (p) p-type silicon carbide well layer 132 may be formed either by epitaxial growth or by implanting p-type dopant ions into the upper portion of the n-type drift region 120 to convert the upper portion of the n-type drift layer 120 into the p-type silicon carbide well layer 132. In example embodiments, the moderately-doped p-type well layer 132 may have a p-type dopant concentration of, for example, between 5×10¹⁶ to 1×10¹⁸.

As is further shown in FIG. 8, p-type shielding regions 634 are provided that extend downwardly from the p-wells 132 into the silicon carbide drift region 120. The p-type shielding regions 634 may be moderately or heavily doped (p⁺) silicon carbide regions. For example, each p-type shielding region 634 may have a doping concentration between about 5×10¹⁶ and 1×10²². In other embodiments, each p-type support region 634 may have a doping concentration between about 1×10¹⁸ and 1×10²¹, between about 1×10¹⁹ and 1×10²¹, between about 1×10¹⁷ and 1×10¹⁹, between about 1×10¹⁷ and 1×10²⁰, or between about 1×10¹⁸ and 1×10²¹. The p-type shielding region 634 may have a doping concentration that is graded with depth. In example embodiments, each p-type support region 634 may extend to a depth of between 0.1 microns and 4.0 microns from the upper surface of the semiconductor layer structure 160. In other embodiments, the depth of each p-type shielding region 634 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the p-type shielding regions 634 may be matched with any of the above-listed depths for the p-type shielding regions 634. The p-type shielding region 634 may act to reduce or suppress the electric field levels that form in gate oxide layers 182.

A plurality of gate trenches 680 including a first gate trench 680-1 extends into (i.e., is formed in) an upper portion of the semiconductor layer structure 160. A gate oxide layer 182 may be in and may conform to an interior perimeter of the first gate trench 680-1. Each of the gate trenches may have a first portion 680a and a second portion 680b, which may be arranged adjacent to each other in a crosswise direction perpendicular to a length of the gate trench 680. Each of the gate trenches 680 may have therein a gate electrode 684 therein. The gate electrode 684 may be present in the first portion 680a of the gate trench 680, and may be absent from the second portion 680b of the gate trench 680. The gate oxide layer 182 and/or the intermetal dielectric layer 188 may be present in the second portion 680b of the gate trench 680. Stated differently, conductive material may be absent from the second portion 680b of the gate trench 680. Accordingly, a spacing or distance between the gate electrode 684 on first and second sides thereof and respective first and second sidewalls of the gate trench 680 may be different.

The spacing or separation of the gate electrodes 684 in the power MOSFET 600 removes an overlap between the gate electrodes 684 and the bottom surfaces of the second portions 680c of the gate trenches 680, which acts to reduce the gate capacitance of the power MOSFET 600 in the bottom of the gate trench 680 and decrease the electric field values in these portions of MOSFET 100. Reducing the electric field values in the second portions 680c of the gate trenches 680 also acts to decrease the electric field values in the gate oxide layers 182 that overlap the bottom surfaces of the second portions 680c of the gate trenches 180. Since these are the portions of the gate oxide layers 182 that would otherwise experience the highest electric field values during reverse blocking operation, it can be seen that the spacing or separation between gate electrodes 684 acts to improve the reliability of MOSFET 100 over MOSFETS 1, 2, and 3. On the other hand, forming the gate electrodes 684 such that the second portions 680b of the gate trenches 680 are devoid or free from conductive material may reduce the overall amount of gate electrode material, thereby increasing the resistance of the gate electrodes 180. The size of the spacing between the gate electrode 684 (i.e., a crosswise width of the second portion 680b of the gate trench 680) may be selected to optimize the tradeoff between gate resistance and reliability. This also reduces the amount of channel area.

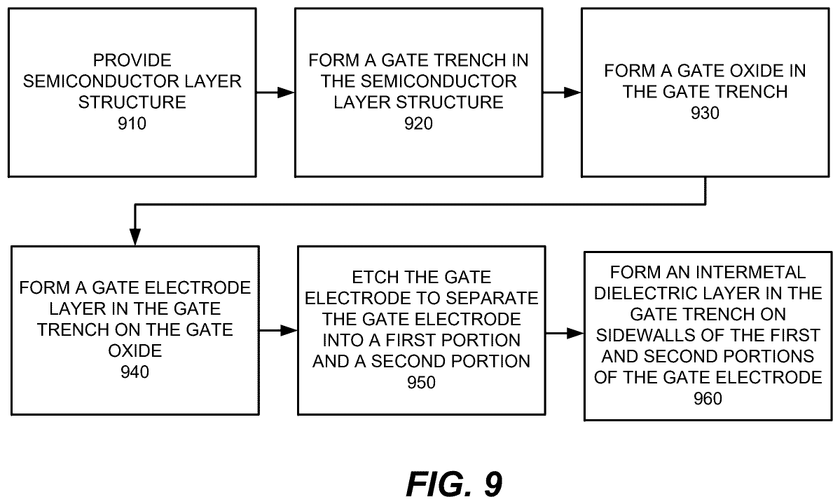

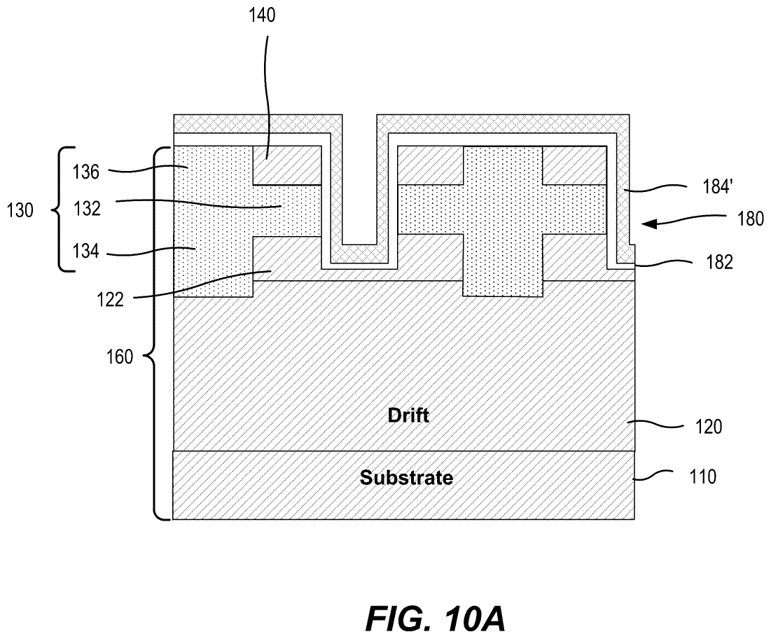

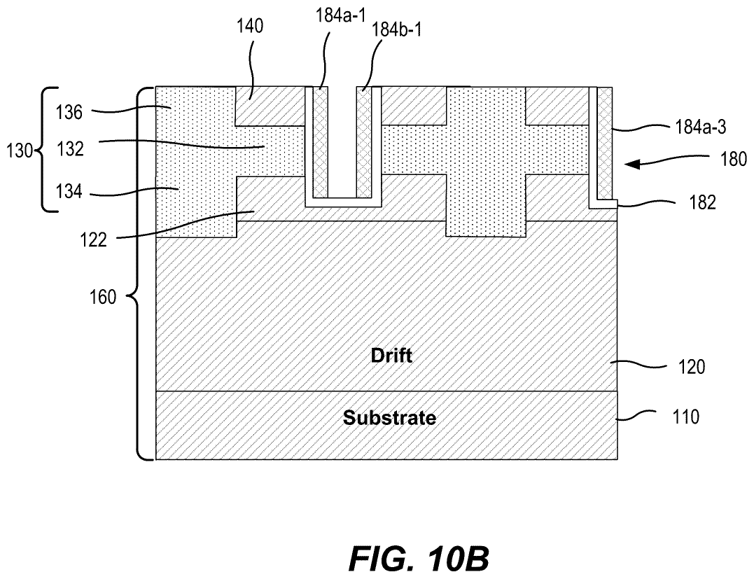

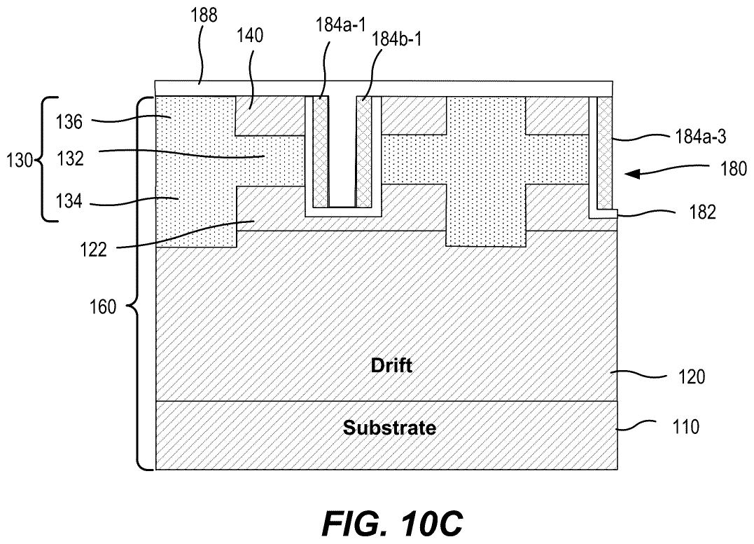

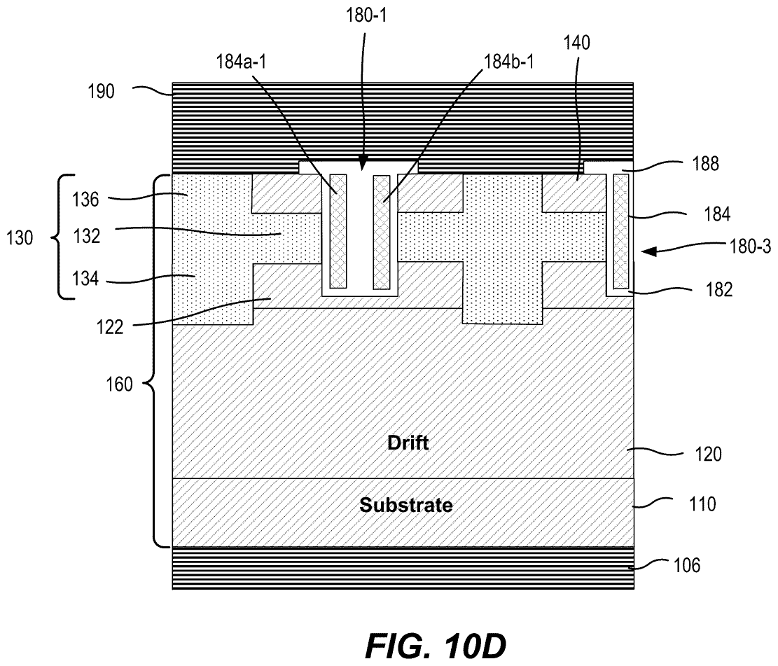

FIG. 9 is a flow chart illustrating a method of fabricating the gate trench silicon carbide power MOSFET of FIGS. 3A-3E. FIGS. 10A-10C are schematic cross-sectional views illustrating a method of fabricating the gate trench silicon carbide power MOSFET of FIGS. 3A-3D.

Referring to FIG. 9, a semiconductor layer structure may be provided (block 910). Referring to FIG. 3E, the n-type silicon carbide substrate 110 may be provided. The lightly-doped n-type silicon carbide drift region 120 may then be formed on an upper surface of the substrate 110 by, for example, epitaxial growth. In some embodiments, the n-type dopant concentration may be increased during the growth of the upper portion of the drift region 120 to form the JFET region 122. In some other embodiments, the n-type dopant concentration may remain the same during the growth of the upper portion of the drift region 120 to form the JFET region 122. A moderately-doped p-type silicon carbide well layer 132 (which may also be referred to as a well layer 132) may then formed on the upper surface of the n-type drift region 120 (i.e., the upper surface of the JFET region 122), either by epitaxial growth or, more commonly, by implanting p-type dopant ions into the upper portion of the n-type drift region 120 (i.e., into the JFET region 122). P-type support regions 134 and p-type well contact regions 136 may be formed via ion implantation. A heavily-doped silicon carbide source region 140 (which may also be referred to as a source layer 140) may then be formed in an upper portion of the p-type silicon carbide well region 132 by, for example, implanting n-type dopant ions into the upper portion of the well region 132.

Referring to FIG. 9, an etching process may be carried out to form the plurality of gate trenches 180 in the upper portion of the semiconductor layer structure 160 (block 920). Each gate trench 180 may extend laterally (i.e., parallel to a major surface of the semiconductor layer structure 160) across the length (or width) of the power MOSFET (e.g., into the page of FIG. 3D). The gate trenches 180 may extend vertically through the source region 140 and the well region 130, and into the JFET region 122 (i.e., into an upper portion of the drift region 120), as shown in FIG. 3D, and the gate trenches 180 may be spaced apart from each other in a horizontal direction perpendicular to the extension direction. For example, the formation of the gate trenches 180 may convert the well region 130 and the source region 140 into the plurality of well regions 130 and the plurality of source regions 140, respectively. The formation of the gate trenches 180 may also convert the JFET region 122 into the plurality of JFET regions 122. In some embodiments, subsequent to the formation of the gate trenches 180, the trench shielding regions 552 may be formed, e.g., by implanting p-type dopant ions into the semiconductor layer structure 160.

Referring to FIG. 9 and FIG. 10A, the gate oxide layer 182 may be formed in the gate trenches 180 and may cover and conform to the sidewalls and bottom surface (i.e., the interior perimeter) of each gate trench 180 (block 930). A gate electrode layer 184′ may also be formed in the gate trenches on the conformal gate oxide layers 182 (block 940). The gate oxide layer 182 may be on upper surfaces of the well regions 132 or well contact regions 136, on upper surfaces of the source regions 140, and on sidewalls of the well regions 132 and source regions 140 that are exposed by the gate trenches 180. The gate electrode layer 184′ may be formed on the gate oxide layer 182. The gate electrode layer 184′ may be formed of a relatively uniform thickness, such that the gate trench 180 is only partially filled after the formation of the gate electrode layer 184′.

Referring to FIG. 9 and FIG. 10B, the gate electrode layer 184′ may be etched (block 950). The gate electrode layer 184′ may be etched to form separated gate electrode first and second portions 184a and 184b within the gate trench 180. As a result of the etching, the gate electrode layer 184′ may be removed from a middle portion (and specifically, from a top surface of the middle portion) of the gate oxide layer 182 within the gate trench 180. As a result of the etching, the gate oxide layer 182 may be removed from upper surfaces of the well regions 132 or well contact regions 136, and from the upper surfaces of the source regions 140.

Referring to FIG. 9 and FIG. 10C, the intermetal dielectric layers 188 may be formed to cover the inner sidewalls 184ai and 184bi of the first and second portions 184a, 184b, of the gate electrode 184 (block 960). The intermetal dielectric layers 188 may be between and may be on (e.g., directly on or directly contacting) inner sidewalls 184ai and 184bi of the first portion 184a and the second portion 184b of the gate electrode 184. In some embodiments, a width of the intermetal dielectric layer 188 between the first portion 184a and the second portion 184b of the gate electrode 184 in a transverse or horizontal direction perpendicular to an extension direction of the gate trench 180 may be equal to a distance between the first portion 184a and the second portion 184b of the gate electrode 184 in the transverse or horizontal direction. During the formation of the intermetal dielectric layers 188 in the gate trenches 180, the intermetal dielectric layers 188 may also be formed on the upper surfaces of the well regions 132 or well contact regions 136, and on the upper surfaces of the source regions 140, and then removed therefrom e.g., by etching.

Referring to FIG. 10D, the source metallization layer 190 may be formed on the upper surface of the semiconductor layer structure 160 and on the intermetal dielectric layers 188. The drain pad 106 may be formed on the substrate 110 opposite the drift region 120.

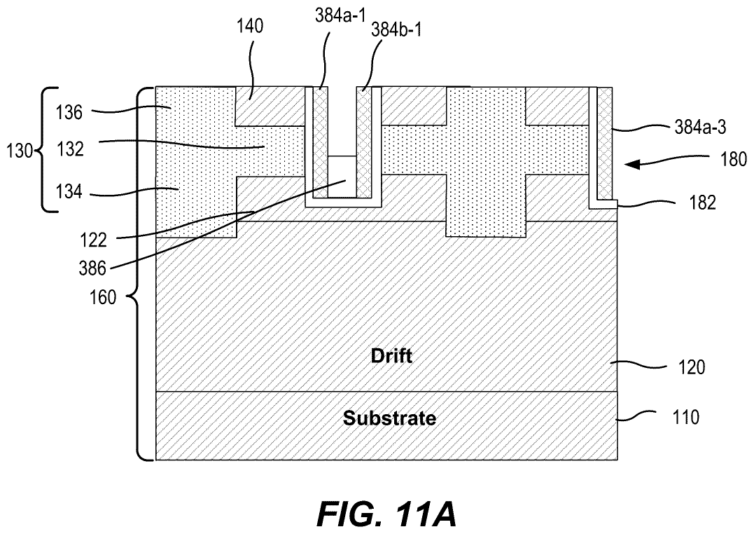

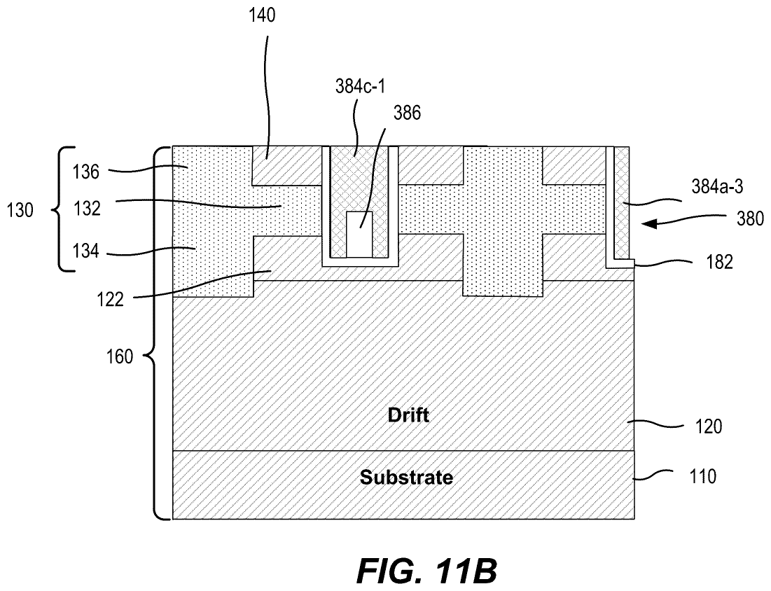

FIGS. 11A and 11B are schematic cross-sectional views illustrating operations of a method of fabricating the gate trench silicon carbide power MOSFET of FIGS. 5A-5C.

Prior to FIG. 11A, operations resulting in FIG. 10B may be performed. That is, as described above with respect to FIGS. 9, 10A, and 10B, a semiconductor layer structure may be provided, gate trenches may be formed in the semiconductor layer structure, gate oxide and gate electrode layers may be formed on the semiconductor layer structure and in the gate trenches, and the gate electrode layers (and gate oxide layer) may be etched, resulting in gate electrodes 384 having separated first portions 384a and second portions 384b. Referring to FIG. 11A, after the gate electrode layer is etched to form the first portion 384a and second portion 384b, an additional insulating material (e.g., additional oxide) may be formed in the gate trench between the first portion 384a and the second portion 384b.

Then, referring to FIG. 11B, an additional gate electrode layer may be formed in the gate trench to form the connecting portion 384c of the gate electrode 384. The connecting portion 384c may be formed in the gate trench 380 between the first portion 384a and the second portion 384b, resulting the gate electrode 384 being formed. An excess portion of the additional gate electrode layer may be removed, e.g., by etching.

Referring to FIG. 5B, the source metallization layer 190 may be formed on the upper surface of the semiconductor layer structure 160 and on the intermetal dielectric layers 188. The drain pad 106 may be formed on the substrate 110 opposite the drift region 120.

Pursuant to the above, and to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench and conforming to an interior perimeter of the first gate trench. The semiconductor device may include a first gate electrode within the first gate trench and on the first dielectric layer, the first gate electrode having first and second portions that are spaced apart from each other by a second dielectric layer.

In some embodiments, at least a portion of the first dielectric layer on a bottom surface of the first gate trench may be free from vertical overlap with the first gate electrode.

In some embodiments, the first and second portions may be free from contact with each other along an entirety of the first gate trench.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer.

In some embodiments, the first dielectric layer may include an oxide.

In some embodiments, the first dielectric layer may have a substantially uniform thickness along the interior perimeter of the first gate trench.

In some embodiments, the first dielectric layer may have a first thickness along a first sidewall of the first gate trench and may have a second thickness along a bottom surface of the first gate trench that is greater than the first thickness.

In some embodiments, the semiconductor layer structure may further include a trench shielding region having the second conductivity type below the first gate trench.

In some embodiments, the semiconductor layer structure may further include a shielding region that extends into the drift region. In some embodiments, the semiconductor device may include a second gate trench extending into the upper portion of the semiconductor layer structure, and the shielding region may be in between the first gate trench and the second gate trench.

In some embodiments, the second dielectric layer may include an oxide.

In some embodiments, the second dielectric layer may be an intermetal dielectric layer.

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending in the semiconductor layer structure. The semiconductor device may furthermore include a first dielectric layer within the first gate trench and conforming to an interior perimeter of the first gate trench. The semiconductor device may in addition include a first gate electrode within the first gate trench and on the first dielectric layer, the first gate electrode having first and second portions that are spaced apart from each other by a second dielectric layer. A maximum width of the second dielectric layer between the first portion and the second portion of the first gate electrode in a transverse direction perpendicular to an extension direction of the first gate trench may be equal to a maximum distance between the first portion and the second portion of the first gate electrode in the transverse direction.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer.

In some embodiments, the first dielectric layer may include an oxide.

In some embodiments, at least a portion of the first dielectric layer on a bottom surface of the first gate trench may be free from overlap with the first gate electrode in a vertical direction perpendicular to the transverse direction.

In some embodiments, the first dielectric layer may have a substantially uniform thickness along the interior perimeter of the first gate trench.

In some embodiments, the first dielectric layer may have a first thickness along a first sidewall of the first gate trench and may have a second thickness along a bottom surface of the first gate trench that is greater than the first thickness.

In some embodiments, the semiconductor layer structure may further include a trench shielding region having the second conductivity type below the first gate trench.

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench and conforming to surfaces of the drift region, well layer, and source region that are exposed by the first gate trench. The semiconductor device may include a first gate electrode within the first gate trench and on the first dielectric layer, the first gate electrode having first and second portions that are spaced apart from each other by a second dielectric layer. The first portion and the second portion of the gate electrode may directly contact the second dielectric layer.

In some embodiments, the first gate electrode may include a connecting portion between and directly connected to the first and second portions of the first gate electrode, and the connecting portion may be at least partially within the first gate trench. In some embodiments, the connecting portion may overlap vertically with the second dielectric layer, and a bottom surface of the connecting portion may directly contact the second dielectric layer.

In some embodiments, the first dielectric layer may include an oxide. In some embodiments, the first dielectric layer and the second dielectric layer may include a same material. In some embodiments, the first dielectric layer and the second dielectric layer may include different materials.

In some embodiments, at least a portion of the first dielectric layer on a bottom surface of the first gate trench may be free from overlap with the first gate electrode in a vertical direction perpendicular to an extension direction of the first gate trench.

According to some embodiments of the inventive concepts of the present disclosure, a method may include providing a semiconductor layer structure that may include a drift region having a first conductivity type. The method may also include forming a gate trench that extends in a longitudinal direction in the semiconductor layer structure. The method may also include forming a first dielectric layer along an interior perimeter of the gate trench. The method may also include forming a gate electrode layer on the first dielectric layer in the gate trench. The method may include etching the gate electrode layer in the gate trench, resulting in a gate electrode having a first portion and a second portion that are spaced apart from each other in a direction perpendicular to the longitudinal direction. The method may also include forming a second dielectric layer between the first portion of the gate electrode and the second portion of the gate electrode.

In some embodiments, the method may include forming an additional gate electrode layer on the second dielectric layer between the first and second portions of the gate electrode.

In some embodiments, the method may include forming a trench shielding region underneath the gate trench into the drift region.

In some embodiments, the first dielectric layer has a first thickness along a first sidewall of the gate trench and has a second thickness along a bottom surface of the gate trench that is greater than the first thickness.

According to some embodiments of the inventive concepts of the present disclosure, a semiconductor device may include a semiconductor layer structure that may include a drift region having a first conductivity type, a well layer having a second conductivity type, and a source region having the first conductivity type. The semiconductor device may also include a first gate trench extending into an upper portion of the semiconductor layer structure. The semiconductor device may include a first dielectric layer within the first gate trench, the first dielectric layer on a bottom surface of the first gate trench. The semiconductor device may include a first gate electrode within the first gate trench and on the first dielectric layer, the first gate electrode having first and second portions that are spaced apart from each other by a second dielectric layer.

In some embodiments, at least a portion of the first dielectric layer on a bottom surface of the first gate trench may be free from vertical overlap with the first gate electrode.

In some embodiments, the first gate electrode further may include a connecting portion between and directly connected to the first and second portions of the first gate electrode, and the connecting portion may be at least partially within the first gate trench.

In some embodiments, the connecting portion may overlap vertically with the second dielectric layer, and a bottom surface of the connecting portion may directly contact the second dielectric layer.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present inventive concepts may cover both n-channel and p-channel devices for each different device structure (e.g., MOSFET, IGBT, etc.).

The present inventive concepts have primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present inventive concepts have been described above with reference to the accompanying drawings, in which embodiments of the inventive concepts are shown. It will be appreciated, however, that the inventive concepts may, however, be embodied in many different forms and should not be construed as limited to the embodiments set forth above. Rather, these embodiments are provided so that this disclosure will be thorough and complete, and will fully convey the scope of the inventive concepts to those skilled in the art. Like numbers refer to like elements throughout.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present inventive concepts. The term “and/or” includes any and all combinations of one or more of the associated listed items.

The terminology used herein is for the purpose of describing particular embodiments only and is not intended to be limiting of the inventive concepts. As used herein, the singular forms “a” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the inventive concepts are described herein with reference to cross-section illustrations that are schematic illustrations of idealized embodiments (and intermediate structures) of the inventive concepts. The thickness of layers and regions in the drawings may be exaggerated for clarity. Additionally, variations from the shapes of the illustrations as a result, for example, of manufacturing techniques and/or tolerances, are to be expected. Embodiments of the inventive concepts are also described with reference to a flow chart. It will be appreciated that the steps shown in the flow chart need not be performed in the order shown.

Some embodiments of the inventive concepts are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the inventive concepts and, although specific terms are employed, they are used in a generic and descriptive sense only and not for purposes of limitation, the scope of the inventive concepts being set forth in the following claims.

1. A semiconductor device, comprising:
a semiconductor layer structure that comprises a drift region having a first conductivity type, a well layer having a second conductivity type, and a source region having the first conductivity type;
a first gate trench extending into an upper portion of the semiconductor layer structure;
a first dielectric layer within the first gate trench and conforming to an interior perimeter of the first gate trench; and
a first gate electrode within the first gate trench and on the first dielectric layer, the first gate electrode having first and second portions that are spaced apart from each other by a second dielectric layer.

2. The semiconductor device of claim 1, wherein at least a portion of the first dielectric layer on a bottom surface of the first gate trench is free from vertical overlap with the first gate electrode.

3. The semiconductor device of claim 1, wherein the first and second portions are free from contact with each other along an entirety of the first gate trench.

4. The semiconductor device of claim 1, wherein the first gate electrode further comprises a connecting portion between and directly connected to the first and second portions of the first gate electrode, and wherein the connecting portion is at least partially within the first gate trench.

5. The semiconductor device of claim 4, wherein the connecting portion overlaps vertically with the second dielectric layer, and wherein a bottom surface of the connecting portion directly contacts the second dielectric layer.

6. The semiconductor device of claim 1, wherein the first dielectric layer comprises an oxide.

7. The semiconductor device of claim 1, wherein the first dielectric layer has a substantially uniform thickness along the interior perimeter of the first gate trench.

8. The semiconductor device of claim 1, wherein the first dielectric layer has a first thickness along a first sidewall of the first gate trench and has a second thickness along a bottom surface of the first gate trench that is greater than the first thickness.

9. The semiconductor device of claim 1, wherein the semiconductor layer structure further comprises a trench shielding region having the second conductivity type below the first gate trench.

10-15. (canceled)

16. A semiconductor device, comprising:
a semiconductor layer structure that comprises a drift region having a first conductivity type, a well layer having a second conductivity type, and a source region having the first conductivity type;
a first gate trench extending in the semiconductor layer structure;
a first dielectric layer within the first gate trench and conforming to an interior perimeter of the first gate trench; and
a first gate electrode within the first gate trench and on the first dielectric layer, the first gate electrode having first and second portions that are spaced apart from each other by a second dielectric layer,
wherein a maximum width of the second dielectric layer between the first portion and the second portion of the first gate electrode in a transverse direction perpendicular to an extension direction of the first gate trench is equal to a maximum distance between the first portion and the second portion of the first gate electrode in the transverse direction.

17. The semiconductor device of claim 16, wherein the first gate electrode further comprises a connecting portion between and directly connected to the first and second portions of the first gate electrode, and wherein the connecting portion is at least partially within the first gate trench.

18. The semiconductor device of claim 17, wherein the connecting portion overlaps vertically with the second dielectric layer, and wherein a bottom surface of the connecting portion directly contacts the second dielectric layer.

19. The semiconductor device of claim 16, wherein the first dielectric layer comprises an oxide.

20. The semiconductor device of claim 16, wherein at least a portion of the first dielectric layer on a bottom surface of the first gate trench is free from overlap with the first gate electrode in a vertical direction perpendicular to the transverse direction.

21. The semiconductor device of claim 16, wherein the first dielectric layer has a substantially uniform thickness along the interior perimeter of the first gate trench.

22. The semiconductor device of claim 16, wherein the first dielectric layer has a first thickness along a first sidewall of the first gate trench and has a second thickness along a bottom surface of the first gate trench that is greater than the first thickness.

23. (canceled)

24. A semiconductor device, comprising:
a semiconductor layer structure that comprises a drift region having a first conductivity type, a well layer having a second conductivity type, and a source region having the first conductivity type;
a first gate trench extending into an upper portion of the semiconductor layer structure;
a first dielectric layer within the first gate trench and conforming to surfaces of the drift region, well layer, and source region that are exposed by the first gate trench; and
a first gate electrode within the first gate trench and on the first dielectric layer, the first gate electrode having first and second portions that are spaced apart from each other by a second dielectric layer,
wherein the first portion and the second portion directly contact the second dielectric layer.

25. The semiconductor device of claim 24, wherein the first gate electrode further comprises a connecting portion between and directly connected to the first and second portions of the first gate electrode, and wherein the connecting portion is at least partially within the first gate trench.

26. The semiconductor device of claim 25, wherein the connecting portion overlaps vertically with the second dielectric layer, and wherein a bottom surface of the connecting portion directly contacts the second dielectric layer.

27. The semiconductor device of claim 24, wherein at least a portion of the first dielectric layer on a bottom surface of the first gate trench is free from overlap with the first gate electrode in a vertical direction perpendicular to an extension direction of the first gate trench.

28-35. (canceled)
